(19) United States
(12) Patent Application Publication
(10) Pub. No.: US 2003/0017700 A1
(43) Pub. Date: Jan. 23, 2003

(54) Process for hillock control in thin film metallization

(76) Inventors: Gary S. Was, Ann Arbor, MI (US); David Srolovitz, Highland Park, NJ (US); Zhenqiang Ma, Ann Arbor, MI (US); Liang Dong, Santa Clara, CA (US)

Correspondence Address: William G. Auton, ESC/JAZ, 40 Wright Street, Hanscom AFB, MA, 01731-2903, US

(21) Appl. No.: 09/910,564

(22) Filed: Jul. 23, 2001

(51) Int. Cl. H01L 21/20; H01L 21/44

(52) U.S. Cl. 438/688; 438/679

(57) ABSTRACT

This invention produces a film which is resistant to hillocking without compromising the electrical conductivity of the interconnects, the circuit architecture or any other function affecting the operation of the integrated circuit. The invention works on the principle that hillocking is caused by the squeezing or extrusion of certain grains (crystals) in the film due to a compressive residual stress state that arises from annealing (heating) treatments applied to the film following the deposition of the film. These grains are in a “weak” crystallographic orientation relative to the great majority of the grains. The coordinated orientation of this great majority of grains is known as the texture and aluminum films are deposited with a strong (111) texture, where (111) refers to specific crystallographic planes and <111>. Refers to the direction normal to the (111) plane. Any grains which are not aligned in the <111> direction, are weaker than those that are and are susceptible to being squeezed out of the plane of the film by the residual stresses imposed by the annealing step. Essentially, the strong grains push on each other and on the weak grains and only the weak grains are squeezed out. Our invention consists of depositing a film with a texture that is mechanically weak. In this way, the great majority of grains will be weak, and under a compressive residual stress, they will deform in a homogeneous manner. The few strong grains will not deform.

### STATEMENT OF GOVERNMENT INTEREST

The invention described herein may be manufactured and used by or for the Government for governmental purposes without the payment of any royalty thereon.

### BACKGROUND OF THE INVENTION

The present invention relates generally to thin film metallization and more specifically to a metallization hillock control process.

A critical step in making integrated circuits is the formation of very thin metal lines (interconnects) that act as miniature wires and conduct electric current between different parts of the circuit. The thin metal lines, known as thin film metallization, are made by deposition techniques such as physical vapor deposition. A major problem with these lines is that they develop large growths, called “hillocks” which can protrude through the material above or below the line and cause a short in the circuit by contacting a neighboring line. They also cause the film to detach from the silicon substrate. They also cause problems with the deposition of subsequent layers on top of the line. One of the largest problems today is that with thin lines made of aluminum because of its susceptibility to hillocking.

The problems of hillock control are recognized in the following U.S. Patents, the disclosures of which are incorporated herein by reference:

U.S. Pat. No. 5,856,235, Jan. 5, 1999, Process of vacuum annealing a thin film metallization on high purity alumina, Koh, and

U.S. Pat. No. 5,729,054, Mar. 17, 1998, Conductive noble-metal-insulator-alloy barrier layer for high-dielectric-constant material electrodes, Summerfelt, and

U.S. Pat. No. 5,696,018, Dec. 9, 1997, Method of forming conductive noble-metal-insulator-alloy barrier layer for high-dielectric-constant material electrodes, Summerfelt and

U.S. Pat. No. 5,382,831, Jan. 17, 1995, Integrated circuit metal film interconnect having enhanced resistance to electromigration, Atakov, and

U.S. Pat. No. 5,057,441, Oct. 15, 1991, Method for reliability testing integrated circuit metal films, Gutt, and

U.S. Pat. No. 3,754,901, Aug. 28, 1973, Evaporation Source for device metallization, Hall.

It is important that high temperatures during manufacturing processing not degrade thin-film metallization once it is deposited. Patterns in the microcircuits may be damaged as a result of diffusion, migration and oxidation, which may cause the thin-film materials to form hillocks or lose their adhesion to the substrate. Thin-film circuits are generally not used with high temperature applications nor processed at temperatures above 400° C. Instead thick film materials are used, but this is a poor solution if thin films are desired.

### SUMMARY OF THE INVENTION

The invention is a process which makes possible the fabrication of aluminum thin film interconnects in semiconductor applications that are more durable and reliable than can be made with current processes. The aluminum interconnects made by this process are resistant to the phenomenon called “hillocking” which is responsible for the failure of integrated circuits in many electronic applications. The immunity to hillocking is achieved with pure Al lines and requires no alloying or capping layers used in other attempts to solve the hillocking problem. The fabrication process has been tested on AL films and it has been verified that annealing at severe temperatures results in no hillocking in the films. This invention will be of interest to all makers of integrated circuits.

This invention produces an aluminum film which is resistant to hillocking without compromising the electrical conductivity of the interconnects, the circuit architecture or any other function affecting the operation of the integrated circuit. The invention works on the principle that hillocking is caused by the squeezing or extrusion of certain grains (crystals) in the film due to a compressive residual stress state that arises from annealing (heating) treatments applied to the film following the deposition of the film. These grains are in a “weak” crystallographic orientation relative to the great majority of the grains. The coordinated orientation of this great majority of grains is known as the texture and aluminum films are deposited with a strong (111) texture, where (111) refers to specific crystallographic planes and <111>. Refers to the direction normal to the (111) plane. Any grains which are not aligned in the <111> direction, are weaker than those that are and are susceptible to being squeezed out of the plane of the film by the residual stresses imposed by the annealing step. Essentially, the strong grains push on each other and on the weak grains and only the weak grains are squeezed out. Our invention consists of depositing a film with a texture that is mechanically weak. In this way, the great majority of grains will be weak, and under a compressive residual stress, they will deform in a homogeneous manner. The few strong grains will not deform.

The control of texture is accomplished by directing a beam of ions onto the substrate during the evaporation of the aluminum film. The ion beam is aligned to be normal to the substrate surface. The ion beam will channel the <110> direction which results in a lower energy deposition rate in grains, with this orientation and a lower sputtering rate. Both of these conditions are conducive to the survival of grains with <110> orientation in preference to grains with <111> orientation. Hence the texture of the film can be changed from predominantly strong <111> oriented grains to predominantly weak oriented <110> grains. The result is that compressive stress from subsequent annealing will not result in the extrusion or squeezing out of weak grains since the weak grains are in the heavy majority and any minority grains are stronger.

### DESCRIPTION OF THE DRAWINGS

There are no figures needed for this invention.

### DESCRIPTION OF THE PREFERRED EMBODIMENT

This invention produces a film which is resistant to hillocking without compromising the electrical conductivity of the interconnects, the circuit architecture or any other function affecting the operation of the integrated circuit. The invention works on the principle that hillocking is caused by the squeezing or extrusion of certain grains (crystals) in the film due to a compressive residual stress state that arises from annealing (heating) treatments applied to the film following the deposition of the film. These grains are in a “weak” crystallographic orientation relative to the great majority of the grains. The coordinated orientation of this great majority of grains is known as the texture and aluminum films are deposited with a strong (111) texture, where (111) refers to specific crystallographic planes and <111>. Refers to the direction normal to the (111) plane. Any grains which are not aligned in the <111> direction, are weaker than those that are and are susceptible to being squeezed out of the plane of the film by the residual stresses imposed by the annealing step. Essentially, the strong grains push on each other and on the weak grains and only the weak grains are squeezed out. Our invention consists of depositing a film with a texture that is mechanically weak. In this way, the great majority of grains will be weak, and under a compressive residual stress, they will deform in a homogeneous manner. The few strong grains will not deform.

The control of texture is accomplished by directing a beam of ions onto the substrate during the evaporation of the aluminum film. The ion beam is aligned to be normal to the substrate surface. The ion beam will channel the <110> direction which results in a lower energy deposition rate in grains, with this orientation and a lower sputtering rate. Both of these conditions are conducive to the survival of grains with <110> orientation in preference to grains with <111> orientation. Hence the texture of the film can be changed from predominantly strong <111> oriented grains to predominantly weak oriented <110> grains. The result is that compressive stress from subsequent annealing will not result in the extrusion or squeezing out of weak grains since the weak grains are in the heavy majority and any minority grains are stronger.

Several alternative solutions have been worked out to combat the problem. First, the aluminum film is alloyed with another element to slow diffusion in the film or strengthen the film. While this may be partly effective, the added elements reduce the electric conductivity of the aluminum film which is a detraction. Films are produced with a “cap” layer of a hard compound which acts to mechanically restrain the protrusion of hillocks out of the aluminum film. The cap layer is often unwanted in the integrated circuit and the solution does not always work. Finally, the growth texture is strengthened. This does not eliminate hillocking.

We have synthesized these films and verified that indeed, the desired texture can be obtained. We have also conducted annealing treatments on these films to show that hillocking is either suppressed or eliminated relative to <111> texture films. The degree of success depends on the strength of the <110> texture. In cases where the product of the ion beam flux and energy are high, there is complete suppression of hillocking on the surface of the films. This is the first such demonstration of a solution to the hillocking problem that does not involve alloying or adding additional layers.

We believe that the market potential for this invention is very large. Essentially, this invention is of interest to all makers of integrated circuits for low power applications. This includes computer makers and their suppliers and numerous other electronics companies. The most uniue benefit of this invention is that it solves an industry problem without introducing any deleterious elements or layers into the IC fabrication process. It can also be implemented using instrumentation which is available today in the marketplace.

While the invention has been described in its presently preferred embodiment, it is understood that the words which have been used are words of description rather than words of limitation and that changes within the purview of the appended claims may be made without departing from the scope and spirit of the invention in its broader aspects.

What is claimed is:

1. A process for controlling hillock formations during metallization of integrated circuits, said process comprising the steps of:
performing a modified deposition step to apply a film of aluminum on a substrate by depositing an aluminum film with a mechanically weak texture by directing an ion beam onto the substrate during deposition of the aluminum film; and
performing an annealing step on the aluminum film to instigate a homogeneous deformation pattern in a weak crystallization orientation relative to other deposits on the substrate, and minimize hillock formation thereby.

2. A process, as defined in claim 1, wherein the performing step includes directing a beam alignment that is normal to the substrate such that when the aluminum film is deposited with a (111) texture, the ion beam channels crystal formation in a <110> direction to instigate said mechanically weak texture and homogeneous deformation pattern in said aluminum film thereby.
